(19) United States
(12) Patent Application Publication
(10) Pub. No.: US 2012/0181066 A1
(43) Pub. Date: Jul. 19, 2012

(54) PACKAGE CARRIER

(75) Inventor: Chih-Hong Chuang, Hsinchu County (TW)

(73) Assignee: SUBTRON TECHNOLOGY CO. LTD., Hsinchu County (TW)

(21) Appl. No.: 13/037,377

(22) Filed: Mar. 1, 2011

(30) Foreign Application Priority Data
Jan. 19, 2011 (TW) 100101977

(51) Int. Cl. H05K 7/20

(52) U.S. Cl. 174/252

(57) ABSTRACT

A package carrier is suitable for carrying a heat-generating element. The package carrier includes a substrate, an insulating structure with high thermal conductivity, and a patterned conductive layer. The substrate has a surface. The insulating structure with high thermal conductivity is configured on a portion of the surface of the substrate. The patterned conductive layer is configured on a portion of the surface of substrate, and a portion of the patterned conductive layer covers the insulating structure with high thermal conductivity. The heat-generating element is suitable for being configured on the portion of the patterned conductive layer which is located on the insulating structure with high thermal conductivity. A coefficient of thermal expansion (CTE) of the insulating structure with high thermal conductivity is between a CTE of the substrate and a CTE of the heat-generating element.

### CROSS-REFERENCE TO RELATED APPLICATION

This application claims the priority benefit of Taiwan application serial no. 100101977, filed Jan. 19, 2011. The entirety of the above-mentioned patent application is hereby incorporated by reference herein and made a part of this specification.

### BACKGROUND OF THE INVENTION

1. Field of the Invention

The invention relates to a package carrier. More particularly, the invention relates to a package carrier requiring high thermal conductivity.

2. Description of Related Art

A chip package provides a chip with proper signal and heat transmission paths and protects the chip structure. A leadframe often serves as a carrier of a chip when a conventional wire bonding technique is applied. As contact density in a chip gradually increases, the leadframe which is unable to further improve the contact density can be replaced by a package substrate which can achieve favorable contact density. Besides, the chip is packaged onto the package substrate by conductive media, such as metal conductive wires or bumps.

In a conventional package process, a coefficient of thermal expansion (CTE) of the chip is rather different from a CTE of the package substrate. Therefore, the chip cannot be well bonded to the package substrate, such that the chip or the bump located between the chip and the package substrate is likely to be peeled off from the package substrate. As the integrity of integrated circuits continues to increase, the mismatch of the CTE between the chip and the package substrate often leads to increasing thermal stress and warpage therebetween. Ultimately, the reliability of the connection between the chip and the package substrate declines.

### SUMMARY OF THE INVENTION

The invention is directed to a package carrier that can effectively lessen the CTE difference when the package carrier carries a heat-generating element, so as to improve the reliability of the package carrier.

In an embodiment of the invention, a package carrier suitable for carrying a heat-generating element is provided. The package carrier includes a substrate, an insulating structure with high thermal conductivity, and a patterned conductive layer. The substrate has a surface. The insulating structure with high thermal conductivity is configured on a portion of the surface of the substrate. The patterned conductive layer is configured on a portion of the surface of substrate, and a portion of the patterned conductive layer covers the insulating structure with high thermal conductivity. The heat-generating element is suitable for being configured on the portion of the patterned conductive layer that is located on the insulating structure with high thermal conductivity, and a CTE of the insulating structure with high thermal conductivity is between a CTE of the substrate and a CTE of the heat-generating element.

According to an embodiment of the invention, the surface of the substrate has a cavity, and the insulating structure with high thermal conductivity is located in the cavity and protrudes from the surface of the substrate.

According to an embodiment of the invention, the package carrier further includes an auxiliary medium layer. The insulating structure with high thermal conductivity includes a first metal layer, a second metal layer, and an insulating material layer with high thermal conductivity. The insulating structure with high thermal conductivity is fixed into the cavity by the auxiliary medium layer. The insulating material layer with high thermal conductivity is configured between the first metal layer and the second metal layer. The second metal layer is located between the insulating material layer with high thermal conductivity and the patterned conductive layer. The first metal layer is located between the insulating material layer with high thermal conductivity and the auxiliary medium layer.

According to an embodiment of the invention, the auxiliary medium layer includes a thermal conductive adhesive layer, a solder layer, or an eutectic layer.

According to an embodiment of the invention, the insulating structure with high thermal conductivity includes a ceramic material layer, an adhesive layer with high thermal conductivity, or an insulating material layer with high thermal conductivity.

According to an embodiment of the invention, the package carrier further includes an insulating via structure, and the substrate has a through hole. The insulating via structure is configured in the through hole. Besides, the insulating via structure includes an insulating layer and a conductive layer. The insulating layer covers an inner wall of the through hole. The conductive layer covers the insulating layer, extends to two opposite surfaces of the insulating layer, and is electrically insulated from the patterned conductive layer. The patterned conductive layer is further configured on the other surface of the substrate opposite to the surface of the substrate.

According to an embodiment of the invention, the heat-generating element includes an electronic chip or a photoelectric element.

According to an embodiment of the invention, the heat-generating element is electrically connected to the patterned conductive layer through wire bonding.

According to an embodiment of the invention, the heat-generating element is electrically connected to the patterned conductive layer through flip-chip bonding.

According to an embodiment, of the invention, the heat-generating element is a chip package which includes a chip and a carrier. The chip is configured on the carrier.

Based on the above, the CTE of the insulating structure with high thermal conductivity is between the CTE of the substrate and the CTE of the heat-generating element according to the embodiments of the invention. Hence, the difference among the CTE of the heat-generating element, the CTE of the insulating structure with high thermal conductivity, and the CTE of the substrate can be gradually reduced. As such, the CTE difference is not significant enough to increase the stress among the heat-generating element, the insulating structure with high thermal conductivity, and the substrate. Thereby, the heat-generating element is not peeled off or damaged, and the reliability of the package carrier can be improved.

In order to make the aforementioned and other features and advantages of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a schematic cross-sectional view illustrating a package carrier that carries a heat-generating element according to an embodiment of the invention.

FIG. 2 is a schematic cross-sectional view illustrating a package carrier that carries a heat-generating element according to another embodiment of the invention.

FIG. 3 is a schematic cross-sectional view illustrating a package carrier that carries a heat-generating element according to still another embodiment of the invention.

FIG. 4 is a schematic cross-sectional view illustrating a package carrier according to an embodiment of the invention.

FIG. 5 is a schematic cross-sectional view illustrating a package carrier according to another embodiment of the invention.

FIG. 6A to FIG. 6G are schematic cross-sectional views illustrating a manufacturing method of a package carrier according to an embodiment of the invention.

### DESCRIPTION OF EMBODIMENTS

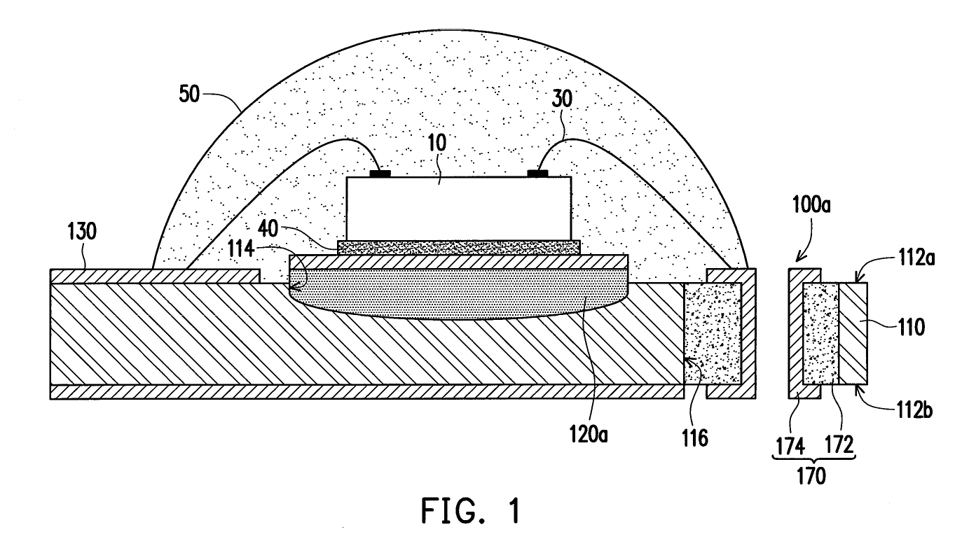

FIG. 1 is a schematic cross-sectional view illustrating a package carrier that carries a heat-generating element according to an embodiment of the invention. With reference to FIG. 1, in this embodiment, the package carrier 100a is suitable for carrying a heat-generating element 10. Here, the heat-generating element 10 includes but is not limited to an electronic chip or a photoelectric element, for instance. The electronic chip can be an integrated circuit chip, e.g., a chip module or an individual chip that includes a graphic chip, a memory chip, and a semiconductor chip. The photoelectric element is a light emitting diode (LED), a laser diode, or a gas discharge light source, for instance. Certainly, the heat-generating element 10 can be any object that can generate heat, such as an operating motor, an operating heater, or the like. In this embodiment, the heat-generating element 10 is a semiconductor chip, for instance.

To be more specific, the package carrier 100a includes a substrate 110, an insulating structure 120a with high thermal conductivity, and a patterned conductive layer 130. The substrate 110 has a surface 112a, the other surface 112b opposite to the substrate 112a, and a cavity 114. Here, the substrate 110 is made of metal with high thermal conductivity (e.g., copper or aluminum), alloy (e.g., cooper alloy or aluminum alloy), or non-metal, while the material of the substrate 110 is not limited to those described above. In addition, the substrate 110 can rapidly transmit the heat generated by the heat-generating element 10, so as to lower the work temperature of the heat-generating element 10.

The insulating structure 120a with high thermal conductivity is configured in the cavity 114 of the substrate 110 and protrudes from the surface 112a of the substrate 110. Here, the cavity 114 of the substrate 110 is coated by or filled with the insulating structure 120a with high thermal conductivity through performing a printing process, and a sintering process is then performed to form the insulating structure 120a with high thermal conductivity. The insulating structure 120a with high thermal conductivity is a ceramic material layer, an adhesive layer with high thermal conductivity, or an insulating material layer with high thermal conductivity, for instance. The adhesive layer with high thermal conductivity is substantially made of a mixture of epoxy and ceramic powder (e.g., Al₂O₃, AlN, or BN). The insulating material layer with high thermal conductivity is, for instance, made of graphite, carbon, Al₂O₃, or AlN and is made by performing a coating process, a foaming process, a sintering process, or a thermal compression process. In addition, when the insulating structure 120a with high thermal conductivity is the adhesive layer with high thermal conductivity, the thickness of the insulating structure 120a with high thermal conductivity ranges from about 2 mm to about 8 mm, for instance. Given the insulating structure 120a with high thermal conductivity is the insulating material layer with high thermal conductivity, the thickness of the insulating structure 120a with high thermal conductivity ranges from about 20 mm to about 30 mm, for instance.

The patterned conductive layer 130 is configured on both a portion of the surface 112a of the substrate 110 and the other surface 112b opposite to the surface 112a. A portion of the patterned conductive layer 130 completely covers the insulating structure 120a with high thermal conductivity. That is to say, the package carrier 100a of this embodiment is a double-sided circuit carrier in substance. The heat-generating element 10 is suitable for being configured on the portion of the patterned conductive layer 130 that is located on the insulating structure 120a with high thermal conductivity through a solder layer 40. In particular, a CTE of the insulating structure 120a with high thermal conductivity is between a CTE of the substrate 110 and a CTE of the heat-generating element 10.

The package carrier 100a of this embodiment can further include an insulating via structure 170, and the substrate 110 further has a through hole 116. The insulating via structure 170 is configured in the through hole 116 and is comprised of an insulating layer 172 and a conductive layer 174. The insulating layer 172 covers an inner wall of the through hole 116. The conductive layer 174 covers the insulating layer 172, extends to two opposite surfaces of the insulating layer 172, and is electrically insulated from the patterned conductive layer 130. Specifically, in this embodiment, the conductive layer 174 and the patterned conductive layer 130 are formed by performing the same manufacturing process, for instance. The heat-generating element 10 (e.g., a semiconductor chip) is electrically connected to the patterned conductive layer 130 and the conductive layer 174 through a plurality of bonding wires 30 by applying the wire bonding technology, for instance. The heat-generating element 10, the bonding wires 30, and a portion of the package carrier 100a can be encapsulated by a molding compound 50, so as to secure the electrical connection among the heat-generating element 10, the bonding wires 30, and the package carrier 100a.

The CTE of the insulating structure 120a with high thermal conductivity is between the CTE of the substrate 110 and the CTE of the heat-generating element 10. Hence, the difference among the CTE of the heat-generating element 10, the CTE of the insulating structure 120a with high thermal conductivity, and the CTE of the substrate 110 can be gradually reduced. As such, the CTE difference is not significant enough to increase the stress among the heat-generating element 10, the insulating structure 120a with high thermal conductivity, and the substrate 110. Thereby, the heat-generating element 10 is not peeled off or damaged, and the reliability of the package carrier 100a can be improved.

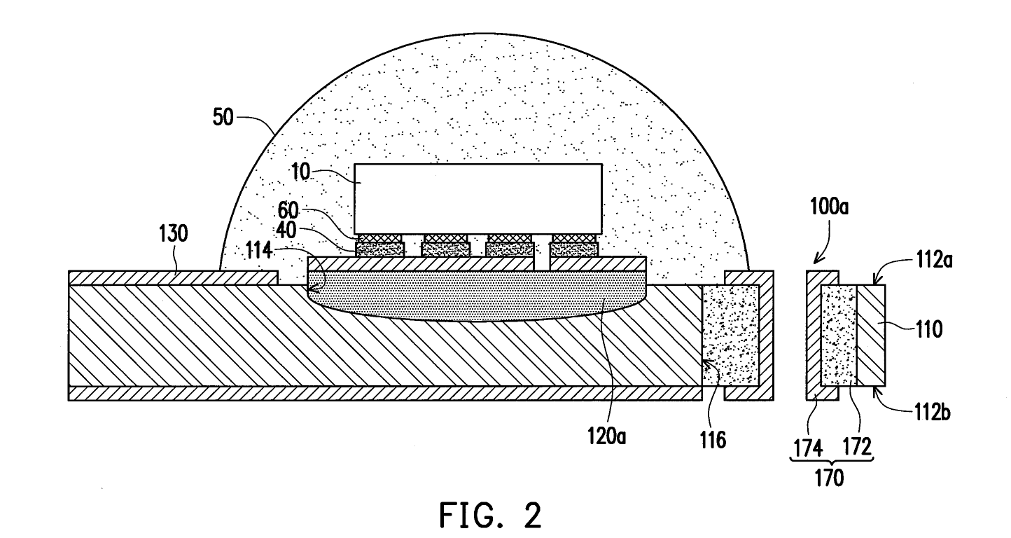

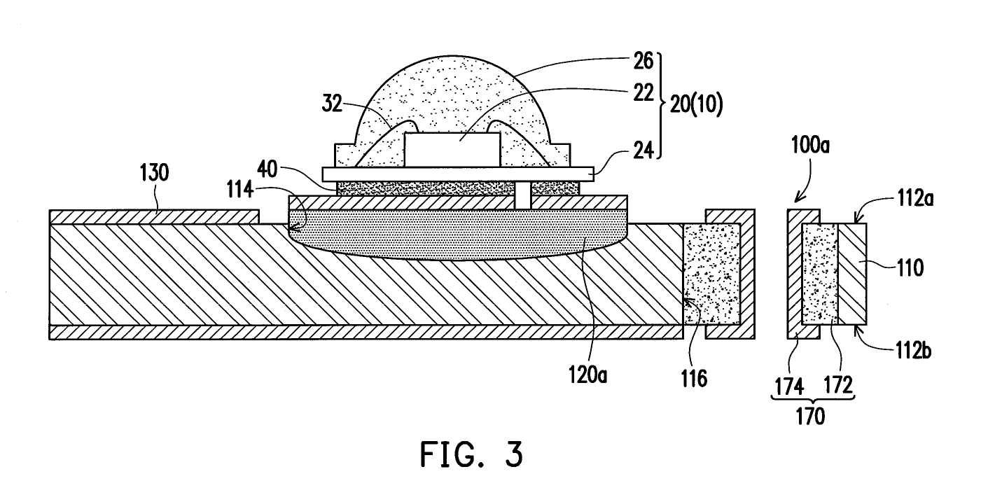

Note that the way to connect the heat-generating element 10 and the package carrier 100a and the type of the heat-generating element 10 are not limited in the invention. Although the heat-generating element 10 described in this embodiment is electrically connected to the conductive layer 170 and the patterned conductive layer 130 of the package carrier 100a by applying the wire bonding technology, the heat-generating element 10 (shown in FIG. 2) in other embodiments of the invention can also be electrically connected to the patterned conductive layer 130 located on the insulating structure 120a with high thermal conductivity through a plurality of bumps 60 by applying a flip-chip bonding technology. Alternatively, as shown in FIG. 3, the heat-generating element 10 is a chip package 20 that is comprised of a chip 22, a carrier 24, and a molding compound 26, for instance. The chip 22 is configured on the carrier 24 and electrically connected to the carrier 24 through a plurality of bonding wires 32. The molding compound 26 encapsulates the chip 22, the bonding wires 32, and a portion of the carrier 24, so as to secure the electrical connection among the chip 10, the bonding wires 32, and the carrier 24. The way to connect the heat-generating element 10 and the package carrier 100a and the type of the heat-generating element 10 are exemplary and should not be construed as limitations to the invention.

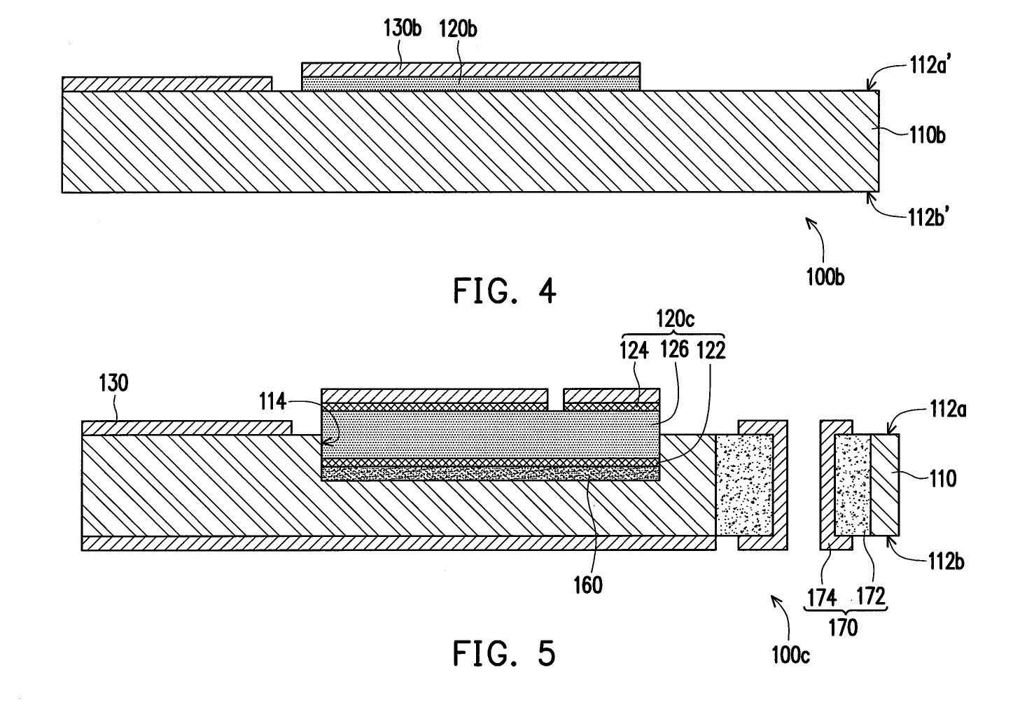

Moreover, the type of the package carrier 100a is not limited in the invention as well. Although the package carrier 100a is a double-sided circuit carrier, and the substrate 110 has the cavity 114, the package carrier 100b (shown in FIG. 4) described in other embodiments of the invention can also be a single-sided circuit carrier, and the substrate 110b does not have the cavity. The insulating structure 120b with high thermal conductivity is directly configured on the surface 112a′ of the substrate 110b. The patterned conductive layer 130b is configured on a portion of the surface 112a′ of the substrate 110b, and a portion of the patterned conductive layer 130b covers the insulating structure 120b with high thermal conductivity.

With reference to FIG. 5, the package carrier 100c can further include an auxiliary medium layer 160, and the insulating structure 120c with high thermal conductivity includes a first metal layer 122, a second metal layer 124, and an insulating material layer 126 with high thermal conductivity. Here, the insulating structure 120c with high thermal conductivity is fixed into the cavity 114 through the auxiliary medium layer 160. The insulating material layer 126 with high thermal conductivity is configured between the first metal layer 122 and the second metal layer 124. The second metal layer 124 is located between the insulating material layer 126 with high thermal conductivity and the patterned conductive layer 130. The first metal layer 122 is located between the insulating material layer 126 with high thermal conductivity and the auxiliary medium layer 160. Specifically, the insulating structure 120a with high thermal conductivity is formed by performing a printing process and then performing a sintering process according to the embodiment depicted in FIG. 1, while the insulating structure 120c with high thermal conductivity in the package carrier 100c is formed by stacking the first and second metal layers 122 and 124 onto the insulating material layer 126 with high thermal conductivity and configuring the stacked first and second metal layers 122 and 124 into the cavity 114 through the auxiliary medium layer 160 by applying a surface mounting technology. The auxiliary medium layer 160 is a thermal conductive adhesive layer, a solder layer, or an eutectic layer, for instance. Hence, the package carrier 100a depicted in FIG. 1 is exemplary and should not be construed as a limitation to the invention.

In other embodiments not shown in the drawings, the heat-generating element 10 can be selectively configured on the substrate 110b that does not have the cavity 114, on the package carrier 100b having the single-sided circuit structure, or on the package carrier 100c having the surface-mount insulating structure 120c with high thermal conductivity, as described in the previous embodiments. Based on the actual requirements, people having ordinary skill in the art can select the aforesaid components with reference to the descriptions of the previous embodiments in order to achieve the desirable technical effects.

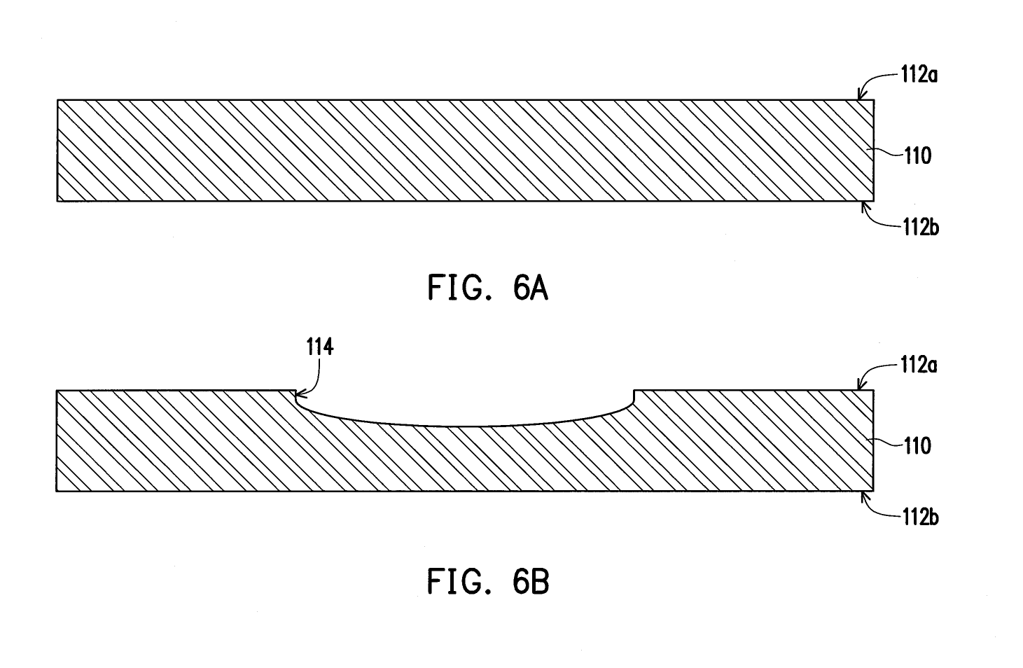

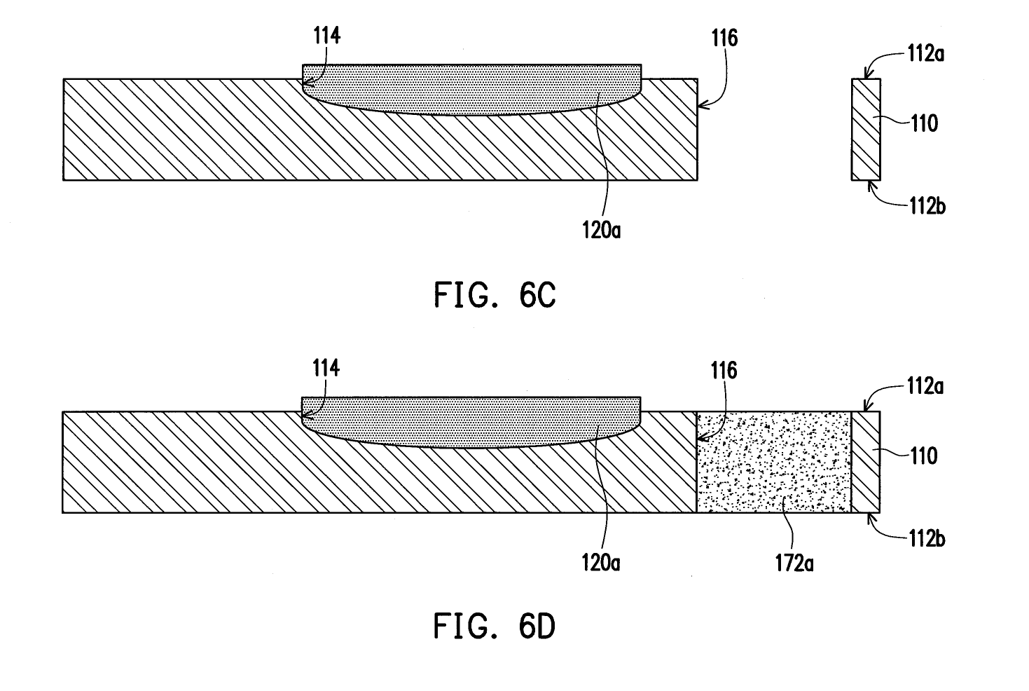

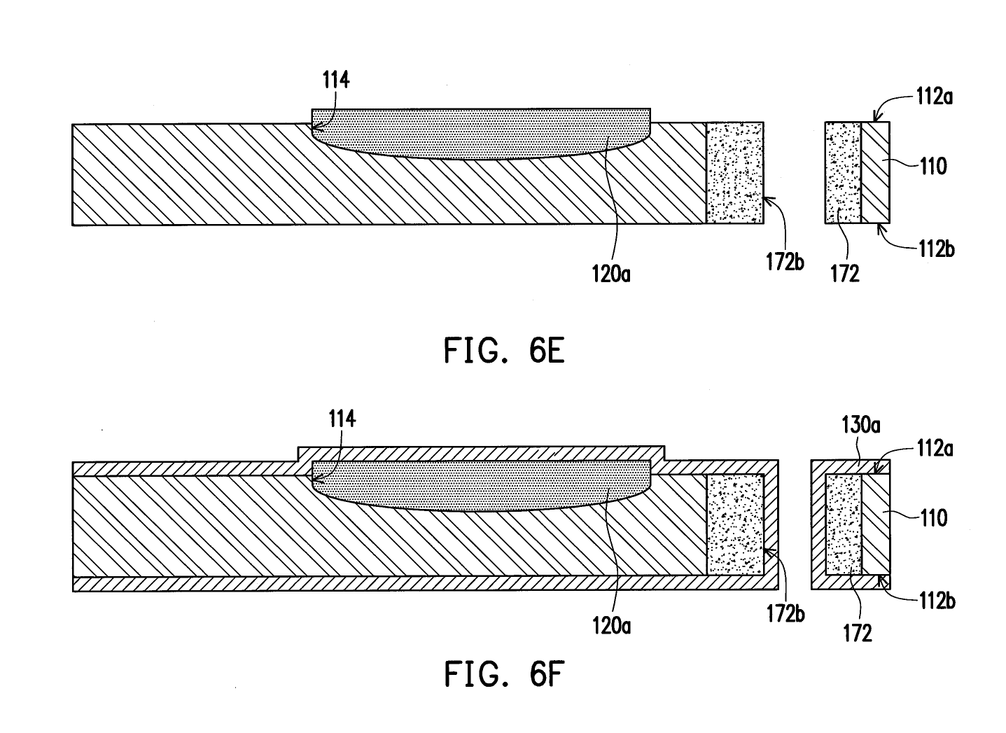

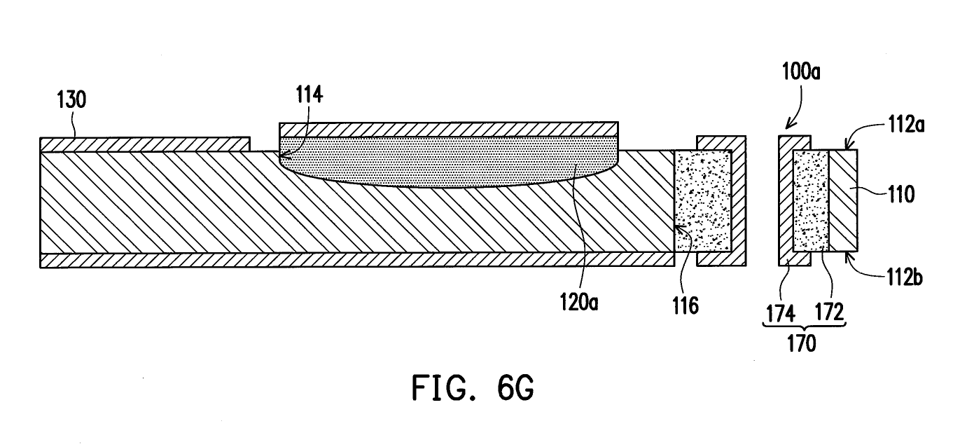

The structures of the package carriers 100a, 100b, and 100c are described above, while the manufacturing method of the package carriers 100a, 100b, and 100c has not yet been introduced. With reference to FIG. 6A to FIG. 6G, the way to manufacture the package carrier 100a described in the previous embodiment is elaborated hereinafter according to another embodiment of the invention. It should be mentioned that some reference numbers and some of the descriptions provided in the previous embodiment are also used in the following exemplary embodiment. The same reference numbers denote the same or like components, and descriptions of the same technical contents are omitted. The aforementioned exemplary embodiment can be referred for descriptions of the omitted parts, and thus the omitted parts are not further described in the following exemplary embodiment.

FIG. 6A to FIG. 6G are schematic cross-sectional views illustrating a manufacturing method of a package carrier according to an embodiment of the invention. As indicated in FIG. 6A, according to the manufacturing method of the package carrier 100a in this embodiment, a substrate 110 is provided. The substrate 110 has a surface 112a and the other surface 112b opposite to the surface 112a.

With reference to FIG. 6B, a cavity 114 is formed on the surface 112a of the substrate 110 by applying stamping, laser, or etching technology. Note that the step of forming the cavity 114 is omitted when the package carrier 100b is formed. Namely, the step of forming the cavity 114 is optional and can be performed based on the users' demands.

With reference to FIG. 6C, the cavity 114 of the substrate 110 is coated by or filled with the insulating material with high thermal conductivity through performing a printing process, and a sintering process is then performed to form the insulating structure 120a with high thermal conductivity. A through hole 116 penetrating the surface 112a and the other surface 112b of the substrate 110 is formed. It should be mentioned that the step of forming the through hole 116 is omitted when the package carrier 100b is formed. Namely, the step of forming the through hole 116 is optional and can be performed based on the users' demands.

With reference to FIG. 6D, the through hole 116 is completely filled with an insulating material layer 172a.

A through hole 172b penetrating the insulating material layer 172a is formed to define an insulating layer 172, as indicated in FIG. 6E.

With reference to FIG. 6F, a conductive layer 130a is formed on the surface 112a and the other surface 112b of the substrate 110. Here, the conductive layer 130a covers the insulating structure 120a with high thermal conductivity and the insulating layer 172, i.e., the conductive layer 130a covers the inner wall of the through hole 172b of the insulating material layer 172a.

As indicated in FIG. 6G, the conductive layer 130a is patterned to form a patterned conductive layer 130. A portion of the patterned conductive layer 130 is configured on both a portion of the surface 112a of the substrate 110 and the other surface 112b opposite to the surface 112a. Besides, a portion of the patterned conductive layer 130 covers the insulating structure 120a with high thermal conductivity. Another portion of the patterned conductive layer 130 (i.e., the conductive layer 174) covers the insulating layer 172, extends to two opposite surfaces of the insulating layer 172, and is electrically insulated from the patterned conductive layer 130. So far, the fabrication of the package carrier 100a is substantially completed.

In light of the foregoing, the CTE of the insulating structure with high thermal conductivity is between the CTE of the substrate and the CTE of the heat-generating element according to the embodiments of the invention. Hence, the difference among the CTE of the heat-generating element, the CTE of the insulating structure with high thermal conductivity, and the CTE of the substrate can be gradually reduced. As such, the CTE difference is not significant enough to increase the stress among the heat-generating element, the insulating structure with high thermal conductivity, and the substrate. Thereby, the heat-generating element is not peeled off or damaged, and the reliability of the package carrier can be improved.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A package carrier suitable for carrying a heat-generating element, the package carrier comprising:
a substrate having a surface;
an insulating structure with high thermal conductivity, configured on a portion of the surface of the substrate; and
a patterned conductive layer configured on a portion of the surface of substrate, a portion of the patterned conductive layer covering the insulating structure with high thermal conductivity, wherein the heat-generating element is suitable for being configured on the portion of the patterned conductive layer located on the insulating structure with high thermal conductivity, and a coefficient of thermal expansion of the insulating structure with high thermal conductivity is between a coefficient of thermal expansion of the substrate and a coefficient of thermal expansion of the heat-generating element.

2. The package carrier as claimed in claim 1, wherein the surface of the substrate has a cavity, and the insulating structure with high thermal conductivity is located in the cavity and protrudes from the surface of the substrate.

3. The package carrier as claimed in claim 2, further comprising an auxiliary medium layer, the insulating structure with high thermal conductivity comprising a first metal layer, a second metal layer, and an insulating material layer with high thermal conductivity, the insulating structure with high thermal conductivity being fixed into the cavity by the auxiliary medium layer, the insulating material layer with high thermal conductivity being configured between the first metal layer and the second metal layer, the second metal layer being located between the insulating material layer with high thermal conductivity and the patterned conductive layer, the first metal layer being located between the insulating material layer with high thermal conductivity and the auxiliary medium layer.

4. The package carrier as claimed in claim 3, wherein the auxiliary medium layer comprises a thermal conductive adhesive layer, a solder layer, or an eutectic layer.

5. The package carrier as claimed in claim 1, wherein the insulating structure with high thermal conductivity comprises a ceramic material layer or an adhesive layer with high thermal conductivity.

6. The package carrier as claimed in claim 1, further comprising an insulating via structure, the substrate having a through hole, the insulating via structure being configured in the through hole and comprising an insulating layer and a conductive layer, the insulating layer covering an inner wall of the through hole, the conductive layer covering the insulating layer, extending to two opposite surfaces of the insulating layer, and being electrically insulated from the patterned conductive layer, the substrate further having the other surface opposite to the surface of the substrate, the patterned conductive layer being configured on the other surface of the substrate.

7. The package carrier as claimed in claim 1, wherein the heat-generating element comprises an electronic chip or a photoelectric element.

8. The package carrier as claimed in claim 1, wherein the heat-generating element is electrically connected to the patterned conductive layer through wire bonding.

9. The package carrier as claimed in claim 1, wherein the heat-generating element is electrically connected to the patterned conductive layer through flip-chip bonding.

10. The package carrier as claimed in claim 1, wherein the heat-generating element is a chip package, the chip package comprising a chip and a carrier, the chip being configured on the carrier.
